(19) United States
(12) Patent Application Publication
(10) Pub. No.: US 2010/0185417 A1
(43) Pub. Date: Jul. 22, 2010

(54) Remote Monitoring of SCADA Ready Field Test Switches

(76) Inventors: Jimmy BOU, Safety Harbor, FL (US); Michael Edward HAAS, New Port Richey, FL (US); Jason RODRIGUES, Toronto (CA)

Correspondence Address: General Electric Company;GE Global Patent Operation, 2 Corporate Drive, Suite 648, Shelton, CT, 06484, US

(21) Appl. No.: 12/624,819

(22) Filed: Nov. 24, 2009

Related U.S. Application Data
(63) Continuation-in-part of application No. 12/356,601, filed on Jan. 21, 2009.

(51) Int. Cl. G06F 15/00; G01R 31/02

(52) U.S. Cl. 702/188; 324/537

(57) ABSTRACT

A device and system for remote monitoring at least one SCADA Ready Field Test (FT) Switch is disclosed. The monitored FT switch relates to the incorporation of a means for providing the output of each at least one FT switch to a remote device to perform an analysis of the status of individual FT switches and providing the status of each FT switch in a manner to identify the FT switch.

### CLAIM OF PRIORITY

This application claims the benefit of the earlier filing date, pursuant to 35 USC 120, as a continuation-in-part to that patent application filed in the US Patent and Trademark Office on Jan. 21, 2009, entitled “SCADA Ready Field Test Switch,” U.S. Ser. No. 12/356,601, the contents of which are incorporated by reference, herein.

### BACKGROUND OF THE INVENTION

In the deployment of large electrical networks and substations systems, testing of the operation of the network and systems is critical to insure proper deployment and operation. Current Field Test (FT) switches provide a simple, immediate and reliable device for isolating industrial equipment and measuring system current and voltage during field testing. Current FT switches, such as the FT-76, manufactured by the General Electric Company, Schenectady, N.Y., includes features necessary for applications involving the measurement of individual currents and voltages to facilitate testing of substation instrumentation and protection devices from the front of an electrical panel. The make-before-break current short circuit feature of the FT-76 allows test personnel the convenience of isolating equipment from current transformer circuits.

In a SCADA (Supervisory, Control and Data Acquisition) system, the FT switch provides a means for providing a reliable means for performing necessary real-live monitoring of the FT switch position. However, because the switches are configured based on the conditions of the subsystem in which they are deployed and because there is redundancy built-in to the switch, there are a number of situations, particularly in the deployment phase, wherein the configuration of the FT switch while appearing to be installed properly, in fact is mis-configured. Another situation may occur wherein after testing of a particular switch, the particular switch is left in an incorrect state and, thus, the FT is mis-configured.

A device as described in the aforementioned related patent application provides for determining the configuration state of each of the switches within a deployed FT switch. However, as these switches may be geographically distributed, technical person may, in some cases, travel to each switch position, even if the switches are geographically local to each other, in order to determine whether the switches are properly configured.

Hence, there is a need to provide a device and means to provide information associated with a plurality of distributed SCADA switches to a centralized location to determine switch configurations and reduce the burden on technical personnel of having to physically access or inspect individual switches.

### SUMMARY OF THE INVENTION

As described herein, the embodiments of the present invention overcome one or more of the above or other disadvantages known in the art.

One aspect of the present invention relates to the incorporation of a monitoring mode for each FT switch among a plurality of switches to monitor the position of individual FT switch units.

Another aspect of the present invention provides for the output of each monitored FT switch to indicate a mis-configuration of individual switch elements of the FT switch.

In another aspect of the present invention the status of the FT switch switches may be remotely monitored.

These and other aspects and advantages of the present invention will become apparent from the following detailed description considered in conjunction with the accompanying drawings.

### BRIEF DESCRIPTION OF THE DRAWINGS

In the Figures:

FIG. 1 illustrates a back panel of a conventional FT switch;

FIG. 2 illustrates a schematic drawing of an exemplary FT switch configuration;

FIG. 3 illustrates a serial connection of an FT switch;

FIGS. 4A and 4B illustrates an exemplary serial connection diagram of an FT switch in accordance with the principles of the invention;

FIG. 5A illustrates a first exemplary embodiment in accordance with the principles of the invention;

FIG. 5B illustrates a second exemplary embodiment in accordance with the principles of the invention;

FIG. 6A illustrates a first exemplary embodiment of the interface shown in FIGS. 5A/5B; and

FIG. 6B illustrates a second exemplary embodiment of the interface shown in FIGS. 5A/5B.

It is to be understood, however, that the drawings are designed solely for purposes of illustration and not as a definition of the limits of the invention, for which reference should be made to the appended claims. Moreover, the drawings are not necessarily drawn to scale and that, unless otherwise indicated, they are merely intended to conceptually illustrate the structures and procedures described herein.

### DETAILED DESCRIPTION OF THE PREFERRED EMBODIMENTS OF THE INVENTION

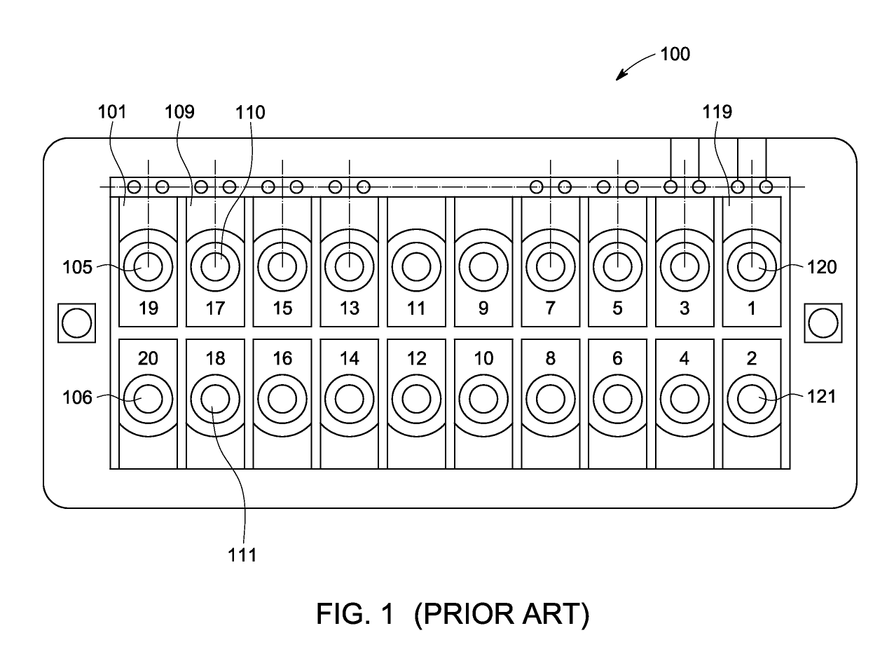

FIG. 1 illustrates a back panel of a conventional FT switch 100. An FT switch is available in a plurality of configurations, ranging from 1 to up to 10 individual switch units; switch unit 101-109 and 119. Each switch unit is conventionally identified by a letter (A-J). Each switch unit includes two terminals e.g., 105, 106 for switch unit 101. The individual switch units are of the knife blade type, typically including a Non-shorting blade or a shorting blade. The knife blade switches can be operated independently or ganged together with a horizontal interlocking.

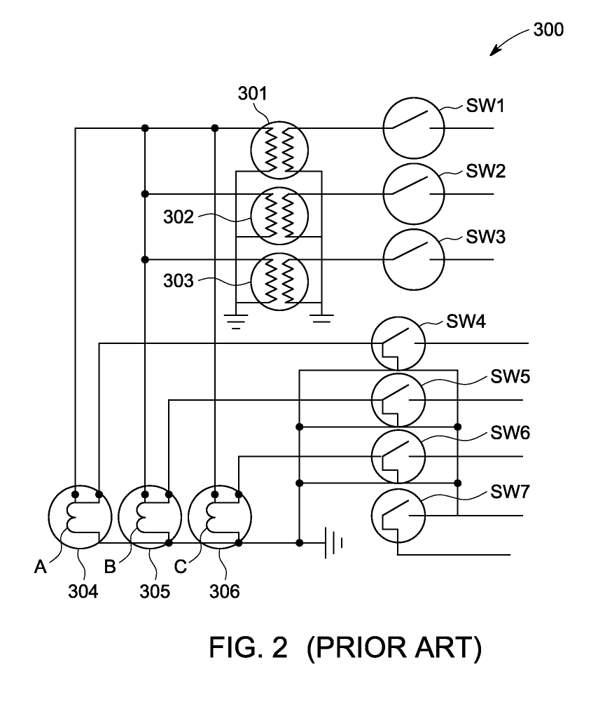

FIG. 2 illustrates an exemplary schematic interconnection diagram of a conventional 10-pole FT switch 300. In this illustrated example, switches SW1, SW2, SW3 are single-pole switches associated with transformers 301, 302, and 303, respectively. Switches SW4, SW5 and SVV6 represent ganged switches that are associated with transformers 304, 305 and 306, respectively. Switches SW4, SW5 and SW6 each allow for the opening of one of the ganged switches to provide a test path for testing transformers 304, 305 and 306, respectively, Switch SW7 is placed in series with output of each of switches 304, 305, and 306. For current measurements with CTs, 2 switch poles must be used per CT to avoid the possibility of leaving a CT OPEN, creating a high voltage hazard at the CT terminals. Opening of one of the 2 switch poles per CT will allow for the testing of current without shutting down power.

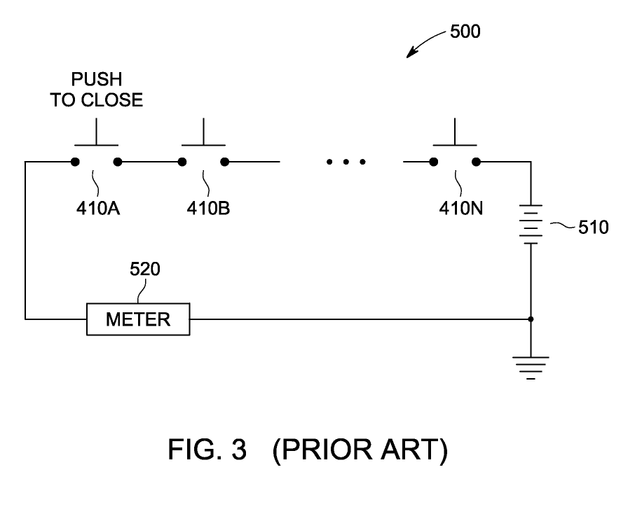

FIG. 3 illustrates an exemplary serial connection 500 of each of a plurality of switch element 410A, 410B, . . . 410N, associated with individual switches, in FT switch 100 (FIG. 1). In this exemplary serial connection, a power source 510, e.g., a DC source such as a battery, photocell, or an AC source, e.g., a rectified AC, provides a voltage to the serial connection of switches 410.A, 410.B . . . 410.N. Meter 520 records essentially the voltage of power source 510 when all of the switches are in a closed position. The output of meter 520 may also be provided to an external device (not shown). The external device may represent a network connection that provides the output of meter 520 to a remote device. The network connection may represent a conventional wired network connection, e.g., serial port, parallel port, to connect to a Local Area Network, a Wide-Area Network, a public network (Internet) or a private network. Or the network connection may represent a wireless network connection to allow connection to a Wi-Fi network, wireless LAN, cellular, and/or satellite network. The output of meter 520 may also be provided to a display (not shown). In this case, when one switch is in an incorrect position, then the whole FT switch is indicated to be in an incorrect configuration.

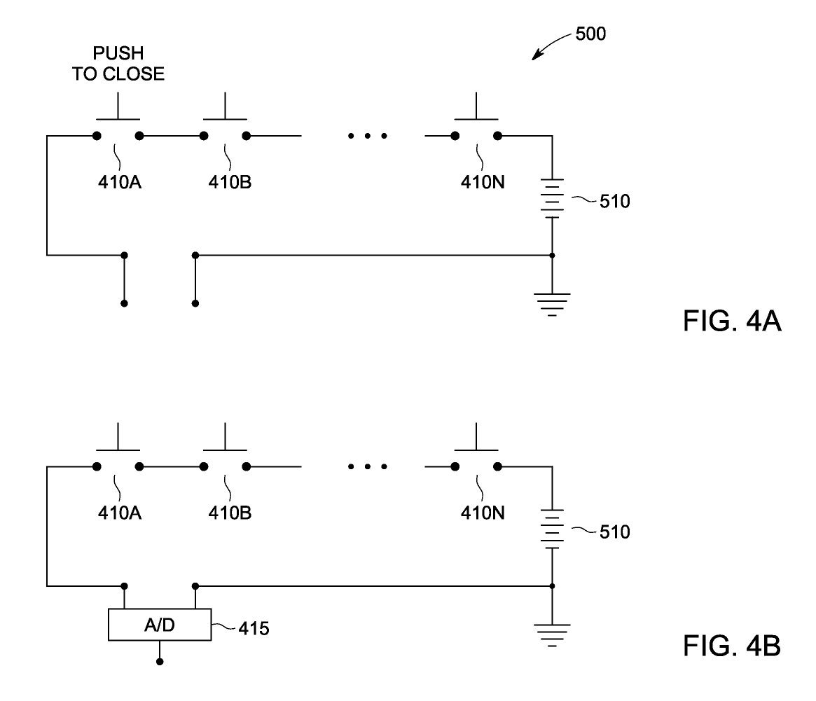

As discussed above, an output meter 520 may be provided to an external device to remotely monitor the configuration of the FT switch. FIG. 4A illustrates an example of the removal of meter 520 from the circuit shown in FIG. 3. In this illustrative case an analog output of the circuit 500 may be directly provided to an external device (not shown). FIG. 4B illustrates an example of the removal of meter 520 from the circuit shown in FIG. 3. In this illustrative case, the output is provided to an Analog/Digital converter 415 to convert the analog output to a digital signal. The output of the A/D 415 is then provided to an external device (not shown). Conversion to a digital signal is advantageous when the distance to the external device is sufficiently large that degradation of the analog signal may result in an incorrect measurement at the external device. In one aspect of the invention, an DNP3 or an MODBUS protocol may be used to communicate digital information to the external device. DNP3 and MODBUS protocols are well-known in art and need not be discussed in detail herein.

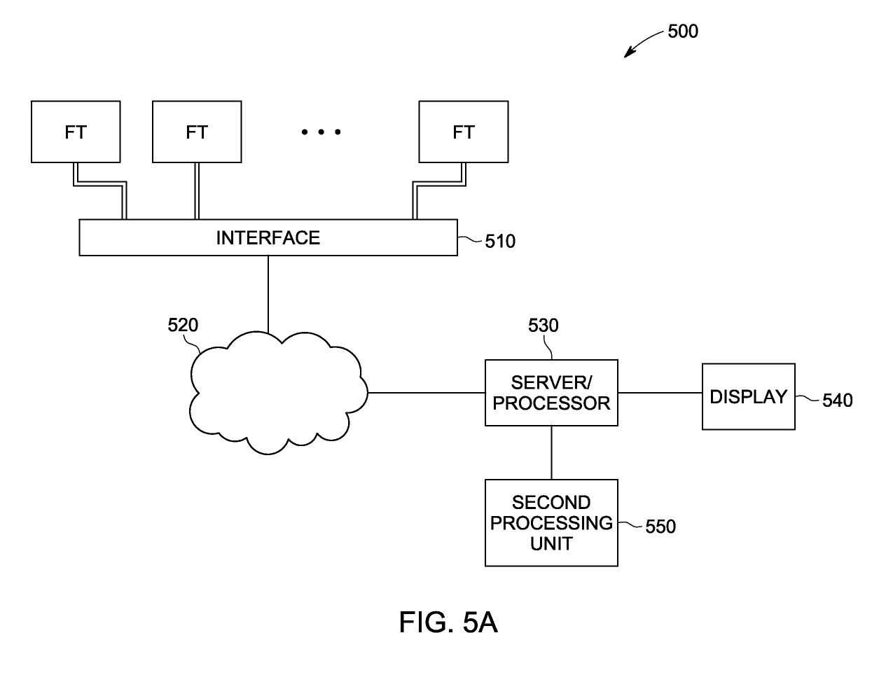

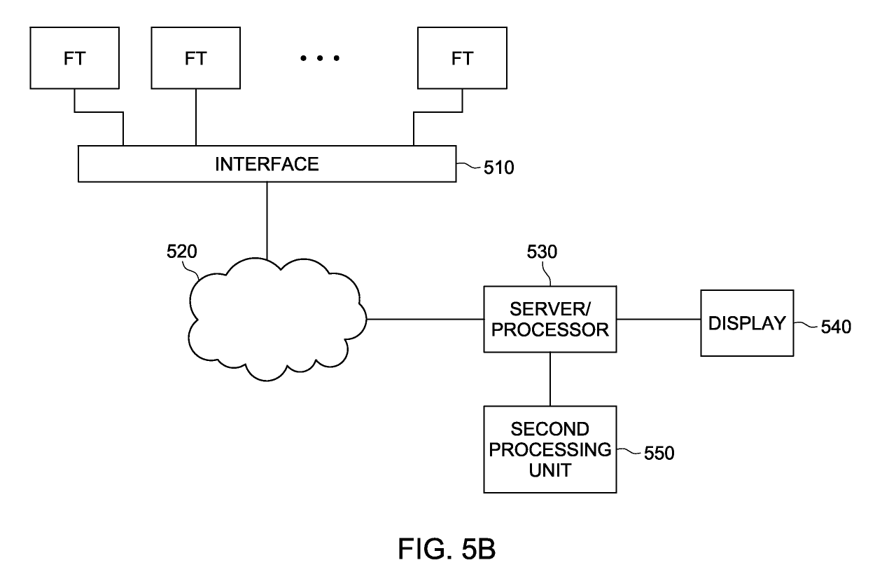

FIG. 5A illustrates a first exemplary embodiment 500 in accordance with the principles of the invention, wherein an output of at least one FT switch 100 is provided to an interface 510 to determine a status of each of the at least one FT switch 100. The status of each switch, along with an overall status of each of the FT switches 100 may then be provided to a network 520 and transferred to one or more servers and/or processors 530 for subsequent processing. The output of the servers and/or processors 530 may then be provided to a display unit 540 or to a second processing unit 550 for additional processing and/or control actions. For example, display unit 540 may provide an indication of each of the individual FT switches and an overall status of all the switches. The second processing unit 550 may cause an action, e.g., prevent power to be applied to an individual FT switch 100 in case an incorrect configuration is determined. In addition, and not shown, it would be recognized that information regarding individual switches (not shown) within each FT switch may also be provided and monitored so that information regarding the FT switch and the individual switch within the FT switch may be provided to technical personnel, if desired. In one aspect of the invention, information may be provided to the servers and/or processors 530 or display unit 540 or second processing unit 550 using one or more network connections that may represent a conventional wired network connection, e.g., a serial port, a parallel port, to connect to a Local Area Network, a Wide-Area Network, a public network (Internet) or a private network. Or the network connections may represent a wireless network connection to allow connection to a Wi-Fi network, a wireless LAN, a cellular, and/or a satellite network. In one aspect of the invention, an DNP3 or an MODBUS protocol may be used to communicate digital information to the aforementioned devices (i.e., processors 530, display 540, second processing unit 550).

In the embodiment shown in FIG. 5A, analog signals may be provided to the interface 510 from corresponding FT switches. That is the voltage level across the meter 520 (FIG. 3) may be provided to the interface. Or the meter 520 may be removed and the analog signals may be provided directly to the interface 510 to determine the status of the corresponding FT switch 100 (FIGS. 4A/4B).

In the embodiment shown in FIG. 5B, digital signals may be provided to the interface 510 from corresponding FT switches 100. The digital signals may represent the output of a comparison of a voltage across meter 520 (FIG. 3) and a reference voltage. For example, in a case when individual switches of the FT switch are properly configured, the output of the FT switch may indicate a first digital value. However, when one or more of the individual switches is not properly configured, then an output of the FT switch 100 may indicate a second digital value.

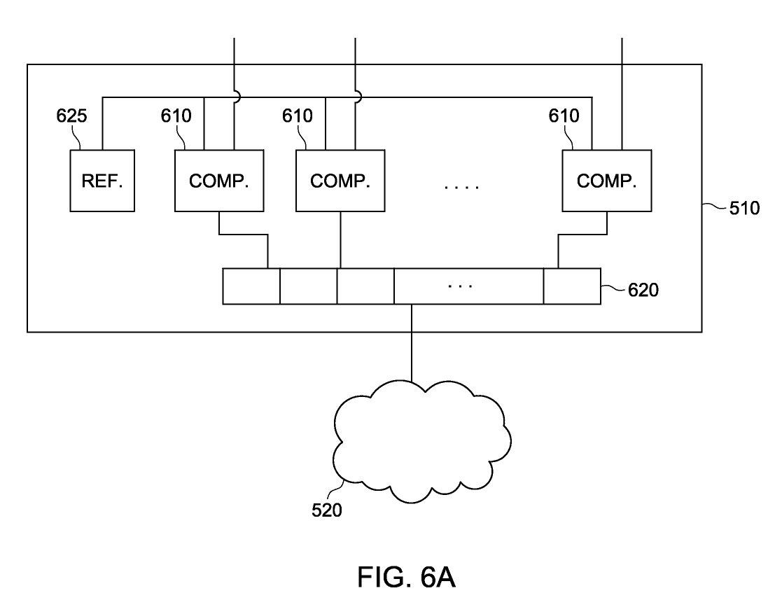

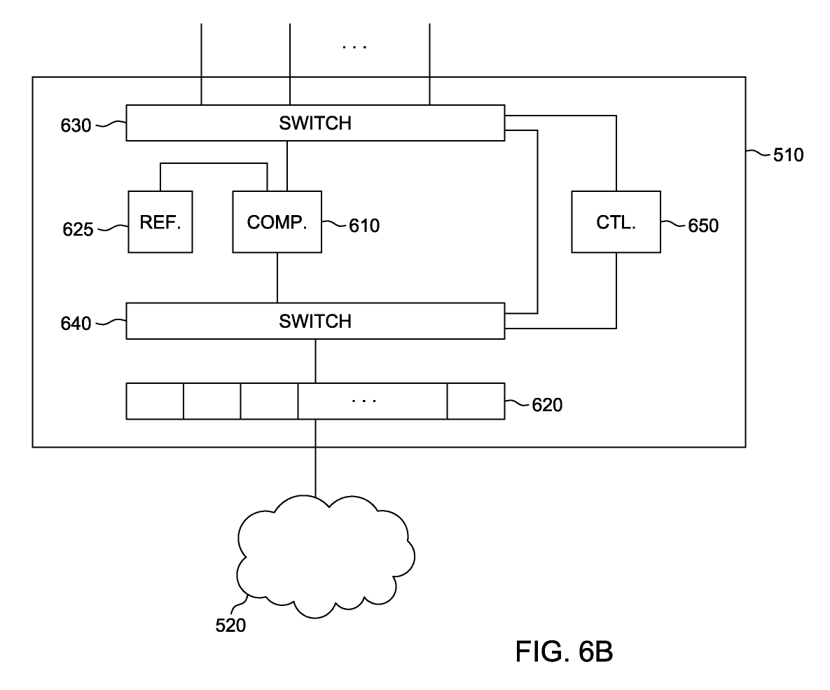

FIG. 6A illustrates a first exemplary embodiment of interface 510 in accordance with the principles of the invention. In this exemplary embodiment, each input from a corresponding FT switch (not shown) is provided to a corresponding comparator circuit 610. A reference value is provided from reference 625 to each of the comparator circuits. In the case when an analog voltage is provided from corresponding FT switches (FIG. 5A) the reference value may be determined based on the voltage value expected when the FT switch is either properly or improperly configured. For example, in the serial connection shown in FIG. 3 of the individual switches of FT switch, a improper configuration results in a zero voltage value. Hence, the reference voltage may be set to be any non-zero voltage greater than an expected noise voltage that may be introduced. Similarly, when a digital value is provided from corresponding FT switches (FIG. 5B), the reference value may be determined based on an expected digital value. For example, when one of the individual switches is not properly configured, the digital output may represent a first digital value (e.g., a zero voltage). Hence, the reference value may be set to a voltage value other than a zero value. Similarly, when a first digital state is represented by a positive voltage value, then the reference value may be set to a value less than the positive value.

In one aspect of the invention shown in FIG. 6A, the results of individual comparisons may be organized as a code word wherein individual positions within the code word represent the status of corresponding comparisons. The code word may then be provided to the network 520 for subsequent display and processing.

Although not shown, it would be recognized that an overall status of network of a plurality of FT switches may be determined by analyzing the code word and a single value (go/no-go) may be provided over the network 520. The single value may be used by technical personnel to evaluate the status of the overall system while requiring a minimum of information transfer. In the case, the single value indicates a no-go condition, then the more detailed code word may be transmitted over the network 520, automatically or upon request by technical personal.

FIG. 6B illustrates a second exemplary embodiment of interface 510 in accordance with the principles of the invention. In this illustrated embodiment, each of the outputs of FT switches (not shown) is provided to a first multi-pole switch 630. A single output of switch 630 is provided to comparator 610 along with reference voltage as previously described. The output of the comparison is provided to a second switch 640, which is maintained in synchronization with first switch 630. The output of the result of the comparator 610 is then provided to second switch 640. Controller 650 maintains first switch 630 and second switch 640 in synchronization. In one aspect of the invention, the position of the first switch 630 corresponds to a known FT switch input and the output of the second switch 630, which, represents the output of the known FT switch, is then inserted into the illustrated code word corresponding to the known FT switch. The result code word or an overall status indicator may be output over network 520 as previously described.

Although not shown, it would be recognized that the output of each FT switch may be provided to an indicator, which indicates one position and/or another position of the corresponding monitoring switch. For example, the indicator may be a light emitting diode (LED) that indicates one or both positions of a corresponding FT switch. In addition, the output provided by the FT switches may be combined and provided to an indicator to represent the configuration of all the FT switches.

The above-described methods according to the present invention can be realized in hardware or as software or computer code that can be stored in a recording medium such as a CD ROM, an RAM, a floppy disk, a hard disk, or a magneto-optical disk or downloaded over a network, so that the methods described herein can be rendered in such software using a general purpose computer, or a special processor or in programmable or dedicated hardware, such as an ASIC or FPGA. As would be understood in the art, the computer, the processor or the programmable hardware include memory components, e.g., RAM, ROM, Flash, etc. that may store or receive software or computer code that when accessed and executed by the computer, processor or hardware implement the processing methods described herein. The code when loaded into a general purpose computer transformed the general purpose computer into a special purpose computer that may in part be dedicated to the processing shown herein.

While there has been shown, described and pointed out fundamental novel features of the invention as applied to preferred embodiments thereof, it will be understood that various omissions and substitutions and changes in the form and details of the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention.

Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

What is claimed is:

1. A field test switch monitoring system comprising:
a plurality of input ports, each associated with a field test switch; said input port receiving a signal indicative of an output of a corresponding field test switch;
a means for:
receiving said signals received on said input ports, and
providing an indication of a status of a corresponding one of said field test switches.

2. The monitoring system of claim 1, wherein said input ports receive one of an analog signal and a digital signal.

3. The monitoring system of claim 2, wherein a first state of the digital signal represents a first condition and a second state of the digital signal represents a second condition of a corresponding FT switch.

4. The monitoring system of claim 2, wherein a first voltage level of the analog signal represents a first condition of a corresponding FT switch.

5. The monitoring system of claim 1, wherein said means comprises:
a comparator receiving one of said inputs and a reference signal, and providing a first indicator output when said received input exceeds said reference signal.

6. The monitoring system of claim 5, wherein said first indicator uniquely identifies said received input.

7. The monitoring system of claim 1 further comprising:
means for providing an overall status indicator representative of an aggregation of the status indicators of corresponding field test switches.

8. The monitoring system of claim 7, wherein said means comprises a comparison of each of said status indicators.

9. The monitoring system of claim 1, further comprising:
means for outputting the status indicators.

10. The monitoring system of claim 9, wherein said output is provided at least to a display system.

11. The monitoring system of claim 1, wherein said means comprises:
a first switch receiving selected ones of said inputs;
a comparator:
receiving outputs of said first switch and a reference value; and
providing a first indicator output when said received output exceeds said reference signal.

12. The monitoring system of claim 11, further comprising:
a second switch, synchronized with said first switch, receiving said first indicator output of the comparator; wherein a position of said first and second switches corresponds to a corresponding one of said field test switches.

13. An interface device comprising:
receiving means for receiving a plurality of input signals, the input signals corresponding to signals output from at least one field test device;
processing means for receiving each of the input signals and determining a status of the at least one field test device corresponding to the received inputs based on a value of the input signal; and
providing an indication of the determined status, wherein the indication uniquely identifies the corresponding at leas t one field test device.

14. The device of claim 13 wherein said processing means comprises:
a processor incorporating a memory the memory including code which when accessed by the processor causes the processor to execute the steps of:
comparing a received input signal value with a reference value; and
providing an indication said reference value at least equals an associated one of said input signal.

15. The device of claim 13, wherein said input means are adapted to receive one of an analog signal and a digital signal.

16. The device of claim 15, wherein said digital signal includes a first state indicating a first condition of said corresponding FT switch and a second state indicating a second condition of said corresponding FT switch.

17. The device of claim 13 further comprising a first switch for receiving each of said input signals and selectively providing said received input signals to a comparator for determining the status of a corresponding FT switch.

18. The device of claim 17, wherein the status indicator is determined when said received input signal to said comparator exceeds a reference signal input to said comparator.
